(19) United States
(12) Patent Application Publication
(10) Pub. No.: US 2024/0162082 A1
(43) Pub. Date: May 16, 2024

(54) MANUFACTURING METHOD OF SEMICONDUCTOR STRUCTURE

(71) Applicant: Powerchip Semiconductor Manufacturing Corporation, Hsinchu (TW)

(72) Inventors: Shih-Ping Lee, Hsinchu City (TW); Shyng-Yeuan Che, Hsinchu County (TW); Ya-Ting Chen, Hsinchu County (TW); Pin-Chieh Huang, Hsinchu County (TW)

(73) Assignee: Powerchip Semiconductor Manufacturing Corporation, Hsinchu (TW)

(21) Appl. No.: 18/150,795

(22) Filed: Jan. 6, 2023

(30) Foreign Application Priority Data
Nov. 11, 2022 (TW) 111143214

(51) Int. Cl. H01L 21/768; H01L 21/311; H01L 23/00; H01L 23/48

(52) U.S. Cl. CPC H01L 21/76802; H01L 21/31116; H01L 21/31144; H01L 23/481; H01L 24/80; H01L 21/76877; H01L 2224/80896

(57) ABSTRACT

A manufacturing method of a semiconductor structure including following steps is provided. A first sacrificial layer and a second sacrificial layer are formed in a first substrate. A first device layer including a first dielectric structure and a first landing pad is formed on the first substrate. A second device layer including a second dielectric structure and a second landing pad is formed on a second substrate. The first dielectric structure is bonded to the second dielectric structure. A portion of the first substrate is removed to expose the first sacrificial layer and the second sacrificial layer. An etch-back process is performed by using the first substrate as a mask to form a first opening exposing the first landing pad and a second opening exposing the second landing pad. A first TSV structure and a second TSV structure are respectively formed in the first opening and the second opening.

### CROSS-REFERENCE TO RELATED APPLICATION

This application claims the priority benefit of Taiwanese application no. 111143214, filed on Nov. 11, 2022. The entirety of the above-mentioned patent application is hereby incorporated by reference herein and made a part of this specification.

### BACKGROUND

### Technical Field

The invention relates to a semiconductor process, and particularly relates to a manufacturing method of a semiconductor structure.

### DESCRIPTION OF RELATED ART

In some semiconductor processes, the dielectric layers on the two substrates are bonded, and then the through-substrate via (TSV) structures are formed. When the above-mentioned bonding process is performed, the overlay shift often occurs. Therefore, the current practice is to increase the size of the landing pad located on the substrate to ensure that the subsequently formed TSV structures can land on the landing pad smoothly. However, increasing the size of the landing pad will increase the size of the chip and reduce the flexibility of the device design.

### SUMMARY

The invention provides a manufacturing method of a semiconductor structure, which is beneficial to reduce the size of the landing pad, thereby reducing the size of the chip and improving the flexibility of the device design.

The invention provides a manufacturing method of a semiconductor structure, which includes the following steps. A first substrate is provided. A first sacrificial layer and a second sacrificial layer are formed in the first substrate. A first device layer is formed on the first substrate. The first device layer includes a first dielectric structure and a first landing pad. The first landing pad is located in the first dielectric structure. A the second substrate is provided. A second device layer is formed on the second substrate. The second device layer includes a second dielectric structure and a second landing pad. The second landing pad is located in the second dielectric structure. The first dielectric structure is bonded to the second dielectric structure, wherein the first sacrificial layer is aligned with the first landing pad, and the second sacrificial layer is aligned with the second landing pad. A portion of the first substrate is removed to expose the first sacrificial layer and the second sacrificial layer. An etch-back process is performed on the first sacrificial layer and the first dielectric structure by using the first substrate as a mask to form a first opening exposing the first landing pad, and the etch-back process is performed on the second sacrificial layer, the first dielectric structure, and the second dielectric structure by using the first substrate as a mask to form a second opening exposing the second landing pad. A first through-substrate via (TSV) structure is formed in the first opening, and a second TSV structure is formed in the second opening.

According to an embodiment of the invention, in the manufacturing method of the semiconductor structure, the first dielectric structure may include a first dielectric layer and a first passivation layer. The first dielectric layer is located on the first substrate, the first sacrificial layer, and the second sacrificial layer. The first landing pad may be located in the first dielectric layer. The first passivation layer is located on the first dielectric layer. The second dielectric structure may include a second dielectric layer and a second passivation layer. The second dielectric layer is located on the second substrate. The second landing pad may be located in the second dielectric layer. The second passivation layer is located on the second dielectric layer.

According to an embodiment of the invention, in the manufacturing method of the semiconductor structure, the method of bonding the first dielectric structure to the second dielectric structure may include bonding the first passivation layer to the second passivation layer.

According to an embodiment of the invention, in the manufacturing method of the semiconductor structure, the method of bonding the first dielectric structure to the second dielectric structure is, for example, a fusion bonding method.

According to an embodiment of the invention, in the manufacturing method of the semiconductor structure, after the portion of the first substrate is removed, the first sacrificial layer and the second sacrificial layer may respectively pass through the first substrate.

According to an embodiment of the invention, in the manufacturing method of the semiconductor structure, the method of removing the portion of the first substrate is, for example, a mechanical grinding method, a wet etching method, a chemical mechanical polishing (CMP) method, or a combination thereof.

According to an embodiment of the invention, in the manufacturing method of the semiconductor structure, the etch-back process is, for example, a dry etching process.

According to an embodiment of the invention, in the manufacturing method of the semiconductor structure, after the first opening and the second opening are formed, a portion of the first sacrificial layer may remain on two sides of the first opening, and a portion of the second sacrificial layer may remain on two sides of the second opening.

According to an embodiment of the invention, in the manufacturing method of the semiconductor structure, the cross-sectional shape of the first sacrificial layer and the cross-sectional shape of the second sacrificial layer may be inverted trapezoids, rectangles, or trapezoids.

According to an embodiment of the invention, the manufacturing method of the semiconductor structure may further include the following step. Before the first TSV structure and the second TSV structure are formed, a liner dielectric layer may be formed on the sidewall of the first opening and the sidewall of the second opening.

Based on the above description, in the manufacturing method of the semiconductor structure according to the invention, after the first dielectric structure is bonded to the second dielectric structure, the first sacrificial layer is aligned with the first landing pad, and the second sacrificial layer is aligned with the second landing pad. In addition, a portion of the first substrate is removed to expose the first sacrificial layer and the second sacrificial layer. Then, the etch-back process is performed on the first sacrificial layer and the first dielectric structure by using the first substrate as a mask to form the first opening exposing the first landing pad, and the etch-back process is performed on the second sacrificial layer, the first dielectric structure, and the second dielectric structure by using the first substrate as a mask to form the second opening exposing the second landing pad. That is, the first opening and the second opening can be formed in a self-aligned manner. Therefore, the manufacturing method of the semiconductor structure according to the invention can have better alignment accuracy, which is beneficial to reduce the size of the first landing pad and the size of the second landing pad, thereby reducing the size of the chip and improving the flexibility of the device design. Furthermore, in the manufacturing method of the semiconductor structure according to the invention, since the openings (e.g., first opening and second opening) for accommodating the TSV structures (e.g., first TSV structure and second TSV structure) can be formed in a self-aligned manner, the number of photomasks can be reduced, thereby reducing the manufacturing cost.

In order to make the aforementioned and other objects, features and advantages of the invention comprehensible, several exemplary embodiments accompanied with drawings are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A to FIG. 1J are cross-sectional views illustrating a manufacturing process of a semiconductor structure according to some embodiments of the invention.

FIG. 2A to FIG. 2B are cross-sectional views illustrating a manufacturing process of a semiconductor structure according to other embodiments of the invention.

FIG. 3A to FIG. 3B are cross-sectional views illustrating a manufacturing process of a semiconductor structure according to other embodiments of the invention.

### DESCRIPTION OF THE EMBODIMENTS

The embodiments are described in detail below with reference to the accompanying drawings, but the embodiments are not intended to limit the scope of the invention. For the sake of easy understanding, the same components in the following description will be denoted by the same reference symbols. In addition, the drawings are for illustrative purposes only and are not drawn to the original dimensions. In fact, the dimensions of the various features may be arbitrarily increased or reduced for clarity of discussion.

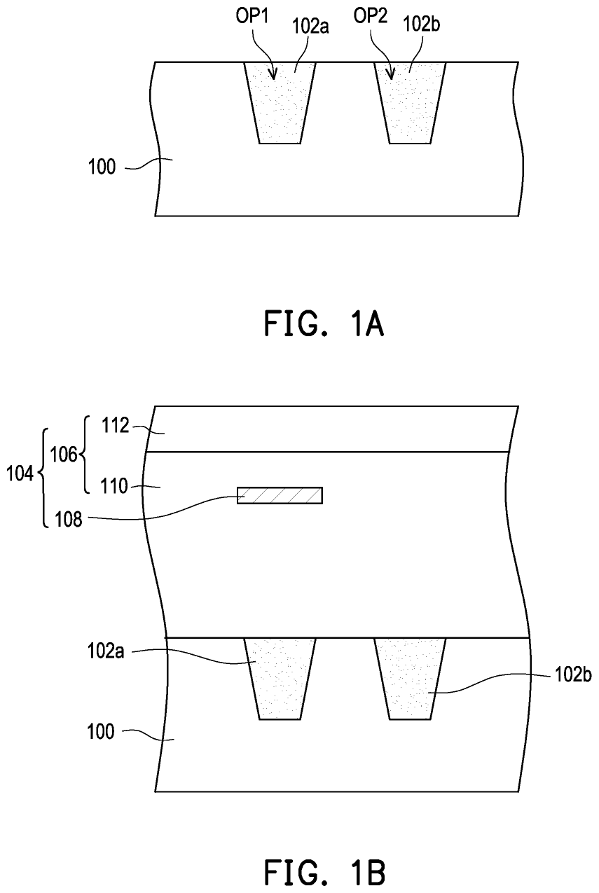

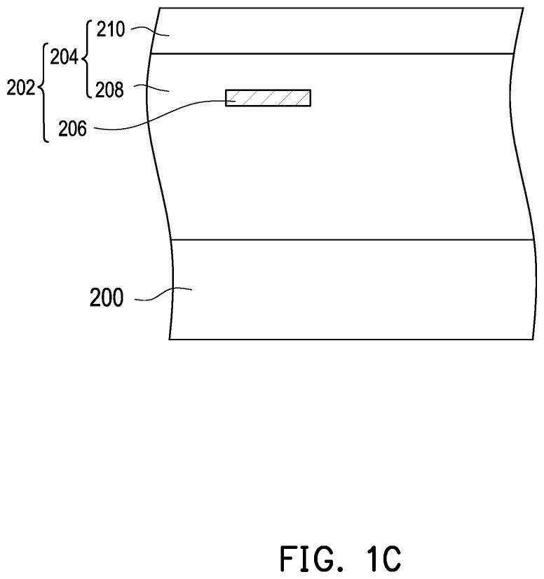

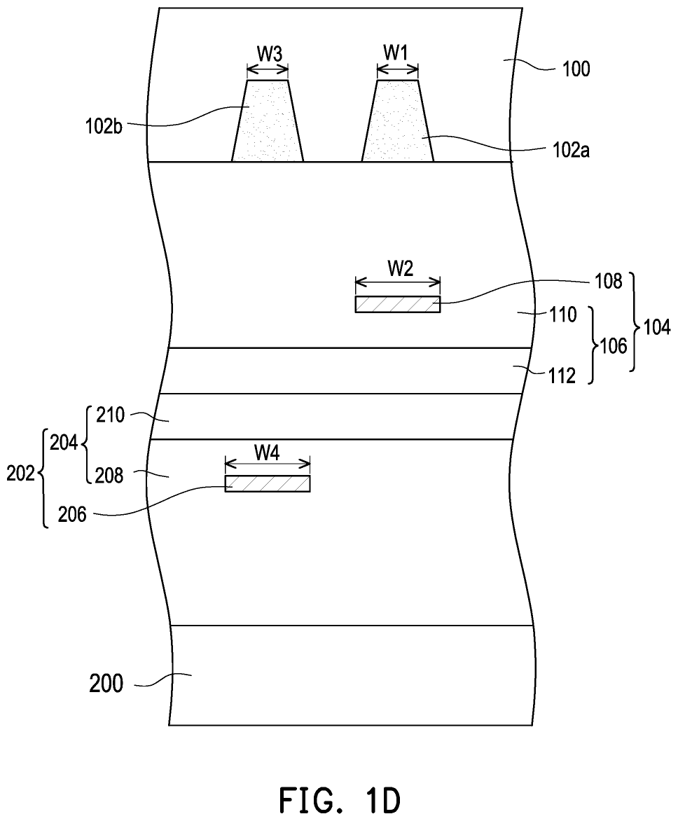

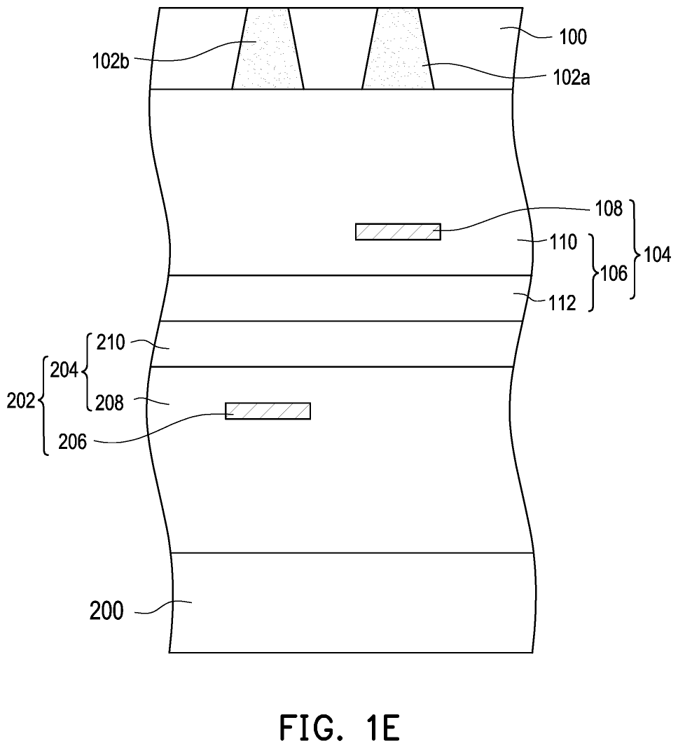

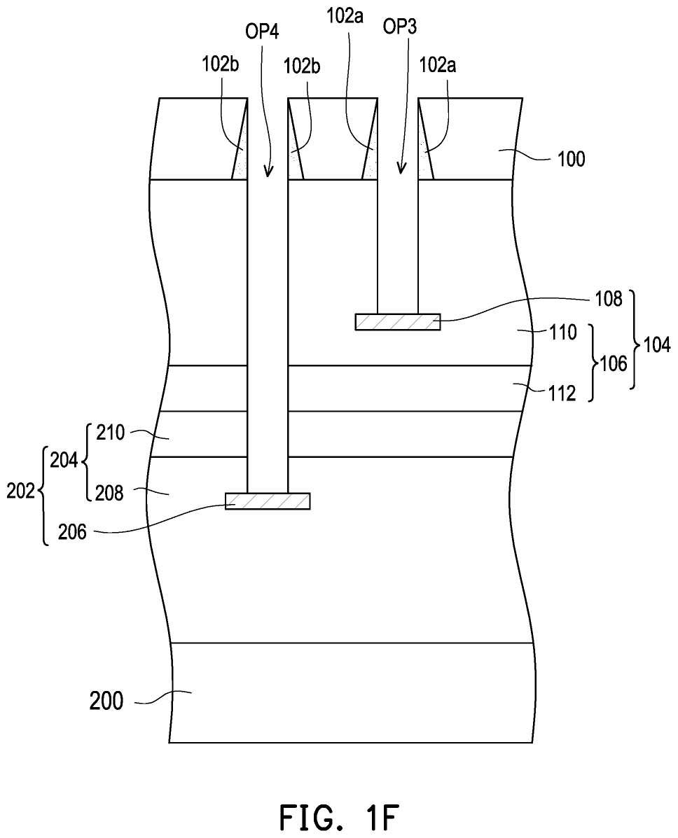

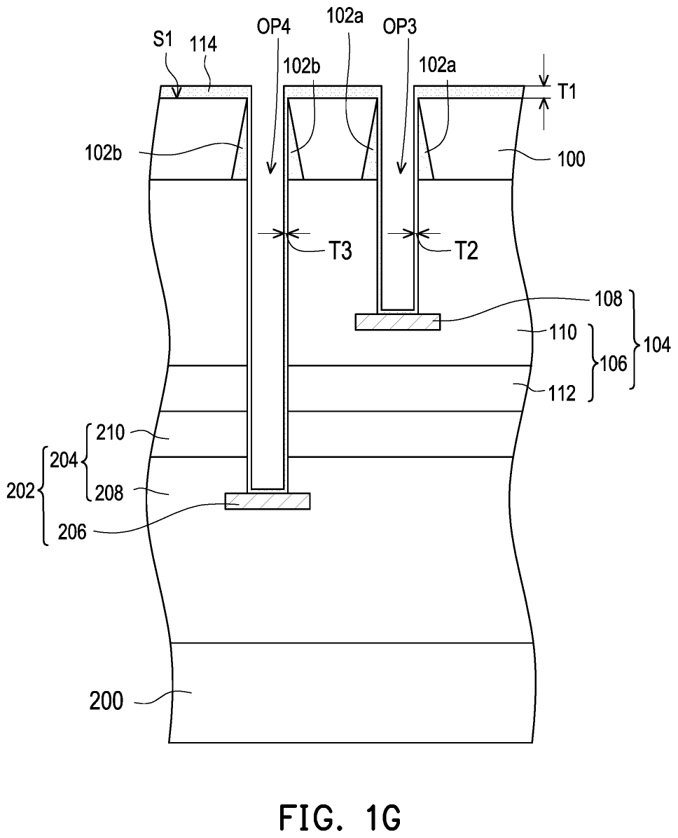

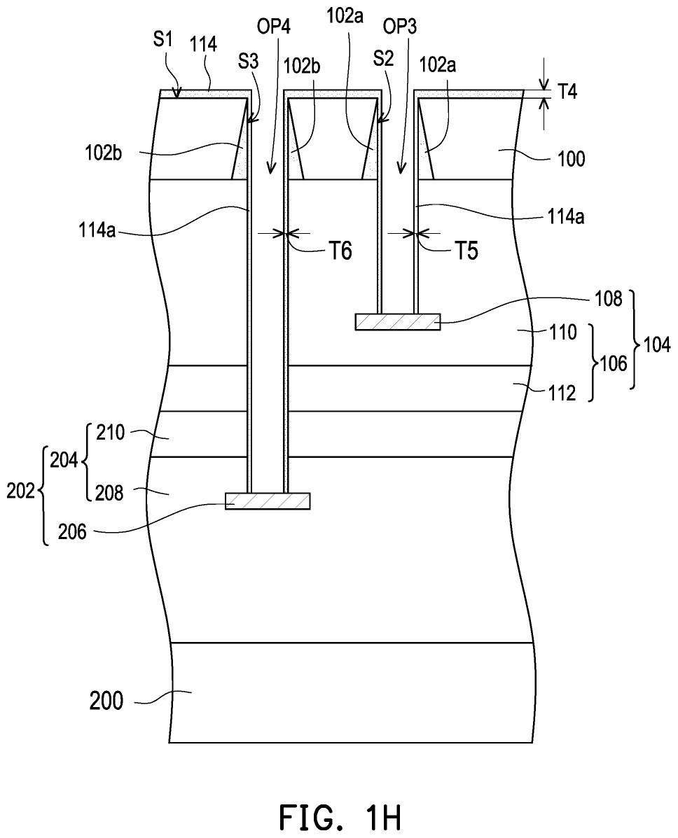

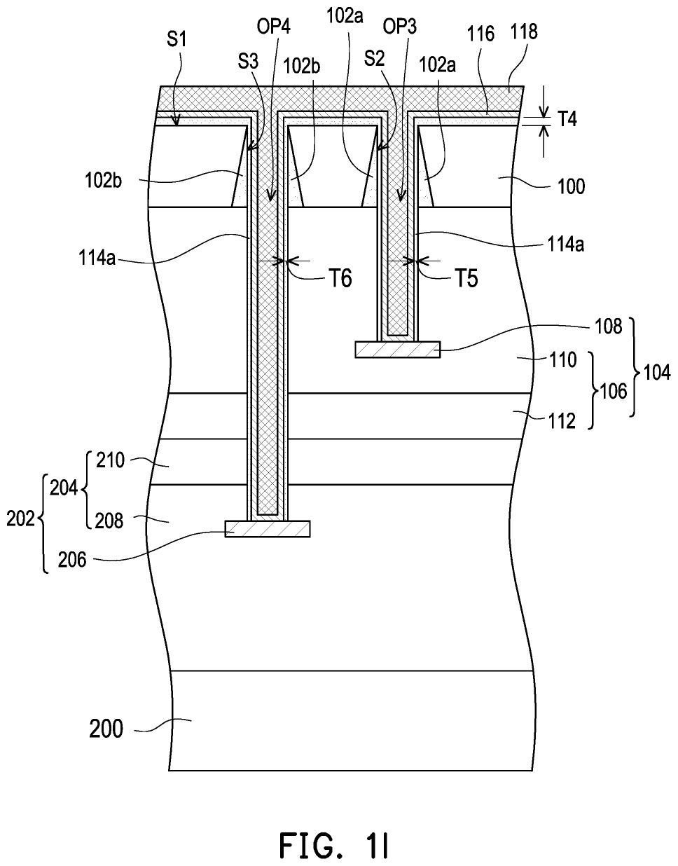

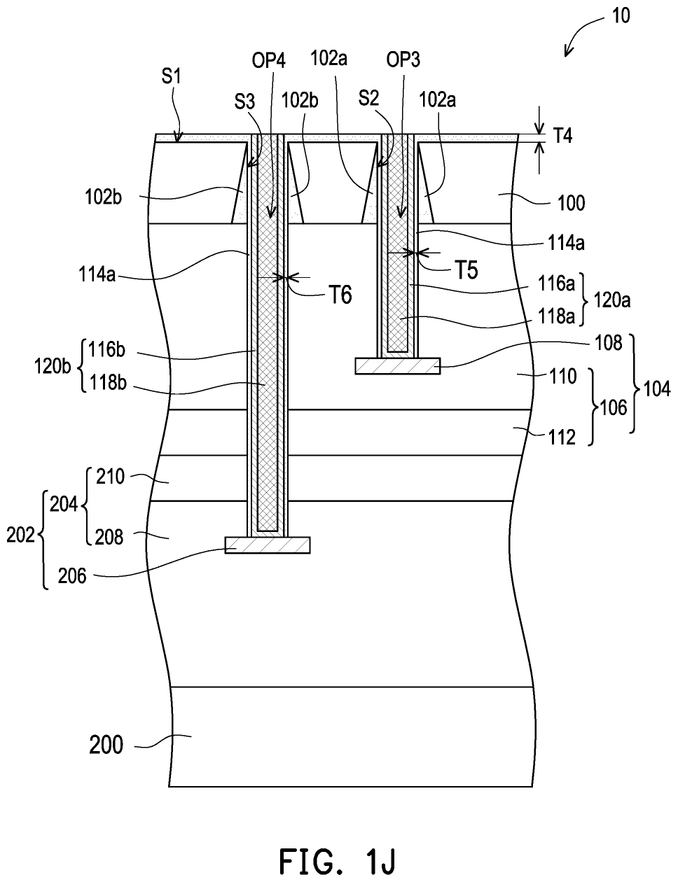

FIG. 1A to FIG. 1J are cross-sectional views illustrating a manufacturing process of a semiconductor structure according to some embodiments of the invention.

Referring to FIG. 1A, a substrate 100 is provided. In some embodiments, the substrate 100 may be a semiconductor substrate such as a silicon substrate. In addition, although not shown in the figure, the substrate 100 may have required components therein, such as doped regions, and the description thereof is omitted here.

A sacrificial layer 102a and a sacrificial layer 102b are formed in the substrate 100. In some embodiments, the material of the sacrificial layer 102a and the material of the sacrificial layer 102b are, for example, dielectric materials such as silicon oxide. In some embodiments, the method of forming the sacrificial layer 102a and the sacrificial layer 102b may include the following steps, but the invention is not limited thereto. First, the substrate 100 may be patterned by a lithography process and an etching process to form an opening OP1 and an opening OP2. Then, a sacrificial material layer (not shown) may be formed on the substrate 100, and the sacrificial material layer fills the opening OP1 and the opening OP2. In some embodiments, the method of forming the sacrificial material layer is, for example, a chemical vapor deposition (CVD) method. Then, the sacrificial material layer located outside the opening OP1 and outside the opening OP2 may be removed to form the sacrificial layer 102a and the sacrificial layer 102b in the opening OP1 and the opening OP2, respectively.

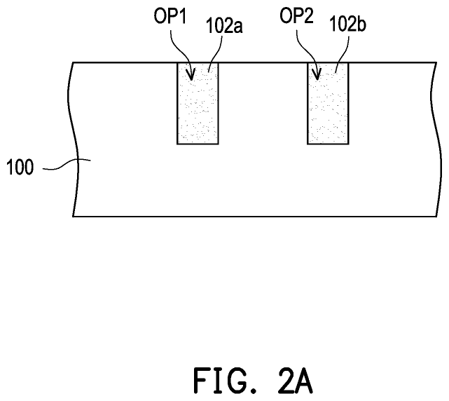

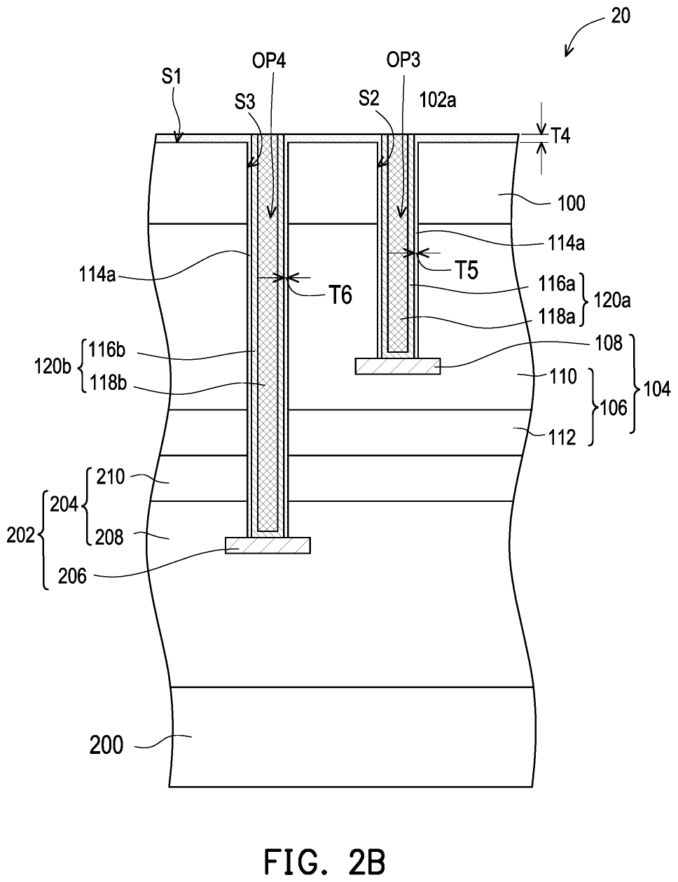

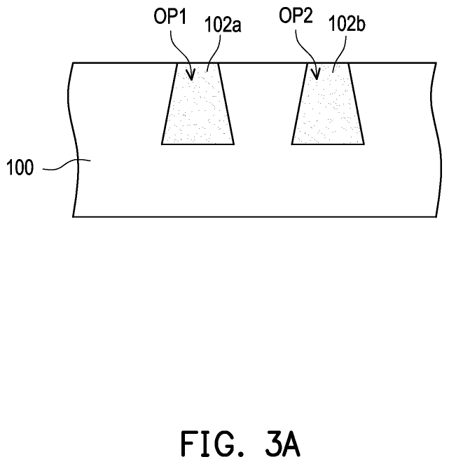

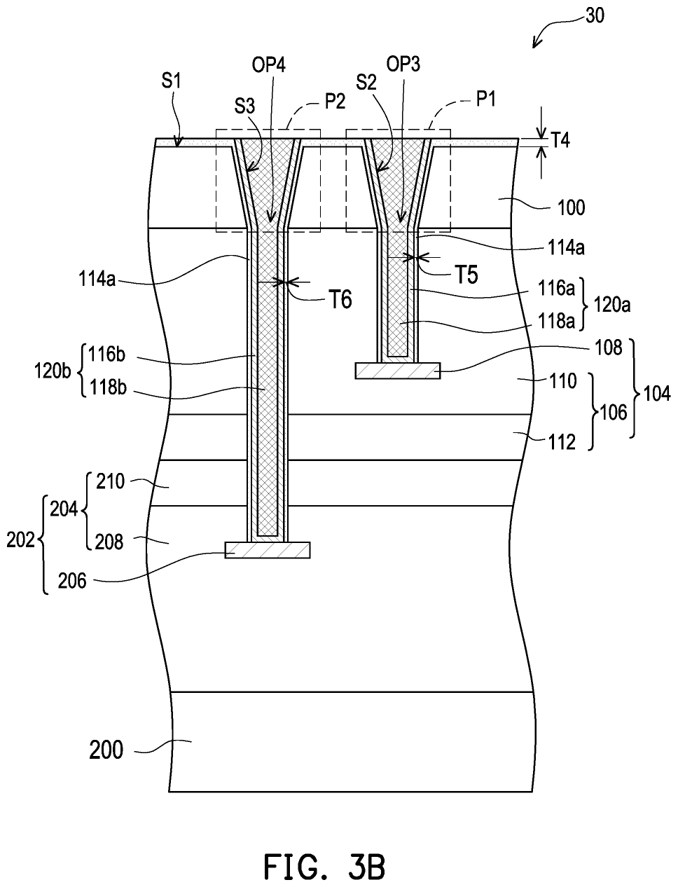

In the present embodiment, the cross-sectional shape of the sacrificial layer 102a and the cross-sectional shape of the sacrificial layer 102b may be inverted trapezoids, but the invention is not limited thereto. In some embodiments, the cross-sectional shape of the opening OP1 and the cross-sectional shape of the opening OP2 may be adjusted by controlling the parameter of the etching process used to form the opening OP1 and the opening OP2, thereby adjusting the cross-sectional shape of the sacrificial layer 102a formed in the opening OP1 and the cross-sectional shape of the sacrificial layer 102b formed in the opening OP2. In other embodiments, the cross-sectional shape of the sacrificial layer 102a and the cross-sectional shape of the sacrificial layer 102b may be rectangles (FIG. 2A) or trapezoids (FIG. 3A).

Referring to FIG. 1B, a device layer 104 is formed on the substrate 100. The device layer 104 includes a dielectric structure 106 and a landing pad 108. The dielectric structure 106 is located on the substrate 100, the sacrificial layer 102a, and the sacrificial layer 102b. The landing pad 108 is located in the dielectric structure 106. In some embodiments, the material of the landing pad 108 is a conductive material such as copper or aluminum. In some embodiments, the device layer 104 may be formed by a front end of line (FEOL) process and a back end of line (BEOL) process.

In some embodiments, the dielectric structure 106 may include a dielectric layer 110 and a passivation layer 112. The dielectric layer 110 is located on the substrate 100, the sacrificial layer 102a, and the sacrificial layer 102b. The landing pad 108 may be located in the dielectric layer 110. In some embodiments, the dielectric layer 110 may be a multilayer structure. In some embodiments, the material of the dielectric layer 110 is, for example, silicon oxide. Furthermore, although not shown in the figure, the dielectric layer 110 may have required semiconductor devices (e.g., active device and/or passive device) therein, and the description thereof is omitted here. The passivation layer 112 is located on the dielectric layer 110. In some embodiments, the material of the passivation layer 112 is, for example, a dielectric material such as silicon oxide.

Referring to FIG. 1C, a substrate 200 is provided. In some embodiments, the substrate 200 may be a semiconductor substrate such as a silicon substrate. In addition although not shown in the figure, the substrate 200 may have required components therein, such as doped regions, and the description thereof is omitted here.

A device layer 202 is formed on the substrate 200. The device layer 202 includes a dielectric structure 204 and a landing pad 206. The dielectric structure 204 is located on the substrate 200. The landing pad 206 is located in the dielectric structure 204. In some embodiments, the material of the landing pad 206 is a conductive material such as copper or tungsten. In some embodiments, the device layer 202 may be formed by a FEOL process and a BEOL process.

In some embodiments, the dielectric structure 204 may include a dielectric layer 208 and a passivation layer 210. The dielectric layer 208 is located on the substrate 200. The landing pad 206 may be located in the dielectric layer 208. In some embodiments, the dielectric layer 208 may be a multilayer structure. In some embodiments, the material of the dielectric layer 208 is, for example, silicon oxide. Furthermore, although not shown in the figure, the dielectric layer 208 may have required semiconductor devices (e.g., active device and/or passive device) therein, and the description thereof is omitted here. The passivation layer 210 is located on the dielectric layer 208. In some embodiments, the material of the passivation layer 210 is, for example, a dielectric material such as silicon oxide.

Referring to FIG. 1D, the dielectric structure 106 is bonded to the dielectric structure 204, wherein the sacrificial layer 102a is aligned with the landing pad 108, and the sacrificial layer 102b is aligned with the landing pad 206. That is, the vertical projection of the sacrificial layer 102a may fall on the landing pad 108, and the vertical projection of the sacrificial layer 102b may fall on the landing pad 206. In some embodiments, the minimum width W1 of the sacrificial layer 102a may be smaller than the width W2 of the landing pad 108. In some embodiments, the minimum width W3 of the sacrificial layer 102b may be smaller than the width W4 of the landing pad 206. In some embodiments, the method of bonding the dielectric structure 106 to the dielectric structure 204 is, for example, a fusion bonding method. In some embodiments, the method of bonding the dielectric structure 106 to the dielectric structure 204 may include bonding the passivation layer 112 to the passivation layer 210. For example, the passivation layer 112 may be bonded to the passivation layer 210 by a fusion bonding method.

In the present embodiment, the number of the sacrificial layers 102a is, for example, one, the number of the sacrificial layers 102b is, for example, one, the number of the landing pads 108 is, for example, one, and the number of the landing pads 206 is, for example, one, but the invention is not limited thereto. As long as the number of the sacrificial layers 102a is at least one, the number of the sacrificial layers 102b is at least one, the number of the landing pads 108 is at least one, and the number of the landing pads 206 is at least one, it falls within the scope of the invention. In other embodiments, the number of the sacrificial layers 102a may be two or more. In other embodiments, the number of the sacrificial layers 102b may be two or more. In other embodiments, the number of the landing pads 108 may be two or more. In other embodiments, the number of the landing pads 206 may be two or more. In addition, the number of the sacrificial layers 102a and the number of the sacrificial layers 102b may be correspondingly adjusted according to the number of the landing pads 108 and the number of the landing pads 206.

Referring to FIG. 1E, a portion of the substrate 100 is removed to expose the sacrificial layer 102a and the sacrificial layer 102b. After the portion of the substrate 100 is removed, the sacrificial layer 102a and the sacrificial layer 102b may respectively pass through the substrate 100. In some embodiments, the method of removing the portion of the substrate 100 is, for example, a mechanical grinding method, a wet etching method, a ClVIP method, or a combination thereof. For example, a mechanical grinding process, a wet etching process, a ClVIP process, or a combination thereof may be performed on the substrate 100 by using the sacrificial layer 102a and the sacrificial layer 102b as a stop layer to remove a portion of the substrate 100 and to expose the sacrificial layer 102a and the sacrificial layer 102b.

Referring to FIG. 1F, an etch-back process is performed on the sacrificial layer 102a and the dielectric structure 106 by using the substrate 100 as a mask to form an opening OP3 exposing the landing pad 108, and the etch-back process is performed on the sacrificial layer 102b, the dielectric structure 106, and the dielectric structure 204 by using the substrate 100 as a mask to form an opening OP4 exposing the landing pad 206. Therefore, the opening OP3 and the opening OP4 can be formed in a self-aligned manner. The opening OP3 and the opening OP4 may be formed by the same etch-back process. In the etch-back process, the landing pad 108 and the landing pad 206 may be used as an etch stop layer. In the present embodiment, after the opening OP3 and the opening OP4 are formed, a portion of the sacrificial layer 102a may remain on two sides of the opening OP3, and a portion of the sacrificial layer 102b may remain on two sides of the opening OP4, but the invention is not limited thereto. In some embodiments, the portion of the sacrificial layer 102a remaining on two sides of the opening OP3 and the portion of the sacrificial layer 102b remaining on two sides of the opening OP4 may have the isolation function. In some embodiments, the etch-back process is, for example, a dry etch process.

Referring to FIG. 1G, a liner dielectric material layer 114 may be conformally formed on the substrate 100 and in the opening OP3 and the opening OP4. In some embodiments, the thickness T1 of the liner dielectric material layer 114 located on the surface S1 of the substrate 100 may be greater than the thickness T2 of the liner dielectric material layer 114 located in the opening OP3 and the thickness T3 of the liner dielectric material layer 114 located in the opening OP4. In some embodiments, the material of the liner dielectric material layer 114 is, for example, silicon oxide. In some embodiments, the method of forming the liner dielectric material layer 114 is, for example, a CVD method.

Referring to FIG. 1H, a portion of the liner dielectric material layer 114 located at the bottom of the opening OP3 and a portion of the liner dielectric material layer 114 located at the bottom of the opening OP4 may be removed to form a liner dielectric layer 114a. Therefore, the liner dielectric layer 114a may be formed on the sidewall S2 of the opening OP3 and the sidewall S3 of the opening OP4. The liner dielectric layer 114a may expose a portion of the landing pad 108 and a portion of the landing pad 206. In some embodiments, the liner dielectric layer 114a may be further formed on the surface S1 of the substrate 100. In some embodiments, the thickness T4 of the liner dielectric layer 114a located on the surface S1 of the substrate 100 may be greater than the thickness T5 of the liner dielectric layer 114a located on the sidewall S2 of the opening OP3 and the thickness T6 of the liner dielectric layer 114a located on the sidewall S3 of the opening OP4. In some embodiments, the material of the liner dielectric layer 114a is, for example, silicon oxide. In some embodiments, the portion of the liner dielectric material layer 114 located at the bottom of the opening OP3 and the portion of the liner dielectric material layer 114 located at the bottom of the opening OP4 may be removed by an etch-back process (e.g., dry etch process).

Referring to FIG. 1I, a barrier material layer 116 may be conformally formed in the opening OP3 and the opening OP4. In some embodiments, the barrier material layer 116 may be formed on the liner dielectric layer 114a, a portion of the landing pad 108, and a portion of the landing pad 206. In some embodiments, the material of the barrier material layer 116 is, for example, tantalum (Ta), tantalum nitride (TaN), or a combination thereof. In some embodiments, the method of forming the barrier material layer 108 is, for example, a physical vapor deposition (PVD) method or a CVD method.

A TSV material layer 118 may be formed on the barrier material layer 116. The TSV material layer 118 may fill in the opening OP3 and the opening OP4. In some embodiments, the material of the TSV material layer 118 is a conductive material such as copper. In some embodiments, a method of forming the TSV material layer 118 is, for example, a PVD method, an electroplating method, or a combination thereof.

Referring to FIG. 1J, a portion of the TSV material layer 118 located outside the opening OP3 and outside the opening OP4 and a portion of the barrier material layer 116 located outside the opening OP3 and outside the opening OP4 may be removed to form a TSV 118a, a TSV 118b, a barrier layer 116a, and a barrier layer 116b. Therefore, the TSV structure 120a may be formed in the opening OP3, and the TSV structure 120b may be formed in the opening OP4. The TSV structure 120a may be electrically connected to the landing pad 108. The TSV structure 120b may be electrically connected to the landing pad 206. In some embodiments, the TSV structure 120a may include the TSV 118a and the barrier layer 116a. The TSV 118a is located in the opening OP3. The barrier layer 116a may be located between the TSV 118a and the liner dielectric layer 114a and between the TSV 118a and the landing pad 108. In some embodiments, the TSV structure 120b may include the TSV 118b and the barrier layer 116b. The TSV 118b is located in the opening OP4. The barrier layer 116b may be located between the TSV 118b and the liner dielectric layer 114a and between the TSV 118b and the landing pad 206.

In some embodiments, the liner dielectric layer 114a may be located between the TSV structure 120a and the substrate 100, between the TSV structure 120a and the dielectric structure 106, between the TSV structure 120b and the substrate 100, between the TSV structure 120b and the dielectric structure 106, and between the TSV structure 120b and the dielectric structure 204.

In the present embodiment, the number of the TSV structures 120a is, for example, one, and the number of the TSV structures 120b is, for example, one, but the invention is not limited thereto. As long as the number of the TSV structures 120a is at least one, and the number of the TSV structures 120b is at least one, it falls within the scope of the invention. In other embodiments, the number of TSV structures 120a may be two or more. In other embodiments, the number of TSV structures 120b may be two or more. In addition, the number of the TSV structures 120a and the number of the TSV structures 120b may be correspondingly adjusted according to the number of the landing pads 108 and the number of the landing pads 206.

Based on the above embodiments, in the manufacturing method of the semiconductor structure 10, after the dielectric structure 106 is bonded to the dielectric structure 204, the sacrificial layer 102a is aligned with the landing pad 108, and the sacrificial layer 102b is aligned with the landing pad 206. In addition, a portion of the substrate 100 is removed to expose the sacrificial layer 102a and the sacrificial layer 102b. Then, the etch-back process is performed on the sacrificial layer 102a and the dielectric structure 106 by using the substrate 100 as a mask to form the opening OP3 exposing the landing pad 108, and the etch-back process is performed on the sacrificial layer 102b, the dielectric structure 106, and the dielectric structure 204 by using the substrate 100 as a mask to form the opening OP4 exposing the landing pad 206. That is, the opening OP3 and the opening OP4 can be formed in a self-aligned manner. Therefore, the manufacturing method of the semiconductor structure 10 can have better alignment accuracy, which is beneficial to reduce the size of the landing pad 108 and the size of the landing pad 206, thereby reducing the size of the chip and improving the flexibility of the device design. Furthermore, in the manufacturing method of the semiconductor structure 10, since the openings (e.g., opening OP3 and opening OP4) for accommodating the TSV structures (e.g., TSV structure 120a and TSV structure 120b) can be formed in a self-aligned manner, the number of photomasks can be reduced, thereby reducing the manufacturing cost.

FIG. 2A to FIG. 2B are cross-sectional views illustrating a manufacturing process of a semiconductor structure according to other embodiments of the invention.

Referring to FIG. 1A and FIG. 2A, the difference between the structure of FIG. 2A and the structure of FIG. 1A is as follows. In FIG. 2A, the cross-sectional shape of the sacrificial layer 102a and the cross-sectional shape of the sacrificial layer 102b may be rectangles. In some embodiments, the cross-sectional shape of the opening OP1 and the cross-sectional shape of the opening OP2 may be adjusted by controlling the parameter of the etching process used to form the opening OP1 and the opening OP2, thereby adjusting the cross-sectional shape of the sacrificial layer 102a formed in the opening OP1 and the cross-sectional shape of the sacrificial layer 102b formed in the opening OP2. In addition, in the structure of FIG. 1A and the structure of FIG. 2A, the same or similar components are denoted by the same reference symbols, and the description thereof is omitted.

Then, the steps as shown in FIG. 1B to FIG. 1J may be performed to form the semiconductor structure 20 in FIG. 2B. In addition, since the cross-sectional shape of the sacrificial layer 102a and the cross-sectional shape of the sacrificial layer 102b in FIG. 2A may be rectangles, the sacrificial layer 102a and the sacrificial layer 102b may be completely removed when the etch-back process for forming the opening OP3 and the opening OP4 as shown in FIG. 1F is performed.

In addition, in the semiconductor structure 10 of FIG. 1J and the semiconductor structure 20 of FIG. 2B, the same or similar components are denoted by the same reference symbols, and the description thereof is omitted.

Based on the above embodiments, in the manufacturing method of the semiconductor structure 20, after the dielectric structure 106 is bonded to the dielectric structure 204, the sacrificial layer 102a is aligned with the landing pad 108, and the sacrificial layer 102b is aligned with the landing pad 206. In addition, a portion of the substrate 100 is removed to expose the sacrificial layer 102a and the sacrificial layer 102b. Then, the etch-back process is performed on the sacrificial layer 102a and the dielectric structure 106 by using the substrate 100 as a mask to form the opening OP3 exposing the landing pad 108, and the etch-back process is performed on the sacrificial layer 102b, the dielectric structure 106, and the dielectric structure 204 by using the substrate 100 as a mask to form the opening OP4 exposing the landing pad 206. That is, the opening OP3 and the opening OP4 can be formed in a self-aligned manner. Therefore, the manufacturing method of the semiconductor structure 20 can have better alignment accuracy, which is beneficial to reduce the size of the landing pad 108 and the size of the landing pad 206, thereby reducing the size of the chip and improving the flexibility of the device design. Furthermore, in the manufacturing method of the semiconductor structure 20, since the openings (e.g., opening OP3 and opening OP4) for accommodating the TSV structures (e.g., TSV structure 120a and TSV structure 120b) can be formed in a self-aligned manner, the number of photomasks can be reduced, thereby reducing the manufacturing cost.

FIG. 3A to FIG. 3B are cross-sectional views illustrating a manufacturing process of a semiconductor structure according to other embodiments of the invention.

Referring to FIG. 1A and FIG. 3A, the difference between the structure of FIG. 3A and the structure of FIG. 1A is as follows. In FIG. 3A, the cross-sectional shape of the sacrificial layer 102a and the cross-sectional shape of the sacrificial layer 102b may be trapezoids. In some embodiments, the cross-sectional shape of the opening OP1 and the cross-sectional shape of the opening OP2 may be adjusted by controlling the parameter of the etching process used to form the opening OP1 and the opening OP2, thereby adjusting the cross-sectional shape of the sacrificial layer 102a formed in the opening OP1 and the cross-sectional shape of the sacrificial layer 102b formed in the opening OP2. In addition, in the structure of FIG. 1A and the structure of FIG. 3A, the same or similar components are denoted by the same reference symbols, and the description thereof is omitted.

Then, the steps as shown in FIG. 1B to FIG. 1J may be performed to form the semiconductor structure 30 in FIG. 3B. In addition, since the cross-sectional shape of the sacrificial layer 102a and the cross-sectional shape of the sacrificial layer 102b in FIG. 3A may be trapezoids, the sacrificial layer 102a and the sacrificial layer 102b may be completely removed when the etch-back process for forming the opening OP3 and the opening OP4 as shown in FIG. 1F is performed. Moreover, as shown in FIG. 3A and FIG. 3B, since the cross-sectional shape of the sacrificial layer 102a and the cross-sectional shape of the sacrificial layer 102b may be trapezoids, the cross-sectional shape of the portion P1 of the TSV structure 120a located in the substrate 100 may include a trapezoid, and the cross-sectional shape of the portion P2 of the TSV structure 120b located in the substrate 100 may include a trapezoid.

In addition, in the semiconductor structure 10 of FIG. 1J and the semiconductor structure 30 of FIG. 3B, the same or similar components are denoted by the same reference symbols, and the description thereof is omitted.

Based on the above embodiments, in the manufacturing method of the semiconductor structure 30, after the dielectric structure 106 is bonded to the dielectric structure 204, the sacrificial layer 102a is aligned with the landing pad 108, and the sacrificial layer 102b is aligned with the landing pad 206. In addition, a portion of the substrate 100 is removed to expose the sacrificial layer 102a and the sacrificial layer 102b. Then, the etch-back process is performed on the sacrificial layer 102a and the dielectric structure 106 by using the substrate 100 as a mask to form the opening OP3 exposing the landing pad 108, and the etch-back process is performed on the sacrificial layer 102b, the dielectric structure 106, and the dielectric structure 204 by using the substrate 100 as a mask to form the opening OP4 exposing the landing pad 206. That is, the opening OP3 and the opening OP4 can be formed in a self-aligned manner. Therefore, the manufacturing method of the semiconductor structure 30 can have better alignment accuracy, which is beneficial to reduce the size of the landing pad 108 and the size of the landing pad 206, thereby reducing the size of the chip and improving the flexibility of the device design. Furthermore, in the manufacturing method of the semiconductor structure 30, since the openings (e.g., opening OP3 and opening OP4) for accommodating the TSV structures (e.g., TSV structure 120a and TSV structure 120b) can be formed in a self-aligned manner, the number of photomasks can be reduced, thereby reducing the manufacturing cost.

In summary, the manufacturing method of the semiconductor structure of the aforementioned embodiments can have better alignment accuracy, which is beneficial to reduce the size of the landing pad, thereby reducing the size of the chip and improving the flexibility of the device design. In addition, in the manufacturing method of the semiconductor structure of the aforementioned embodiments, since the openings for accommodating the TSV structures can be formed in a self-aligned manner, the number of photomasks can be reduced, thereby reducing the manufacturing cost.

Although the invention has been described with reference to the above embodiments, it will be apparent to one of ordinary skill in the art that modifications to the described embodiments may be made without departing from the spirit of the invention. Accordingly, the scope of the invention is defined by the attached claims not by the above detailed descriptions.

What is claimed is:

1. A method manufacturing of a semiconductor structure, comprising:
providing a first substrate;
forming a first sacrificial layer and a second sacrificial layer in the first substrate;
forming a first device layer on the first substrate, wherein the first device layer comprises a first dielectric structure and a first landing pad, and the first landing pad is located in the first dielectric structure;
providing a second substrate;
forming a second device layer on the second substrate, wherein the second device layer comprises a second dielectric structure and a second landing pad, and the second landing pad is located in the second dielectric structure;
bonding the first dielectric structure to the second dielectric structure, wherein the first sacrificial layer is aligned with the first landing pad, and the second sacrificial layer is aligned with the second landing pad;
removing a portion of the first substrate to expose the first sacrificial layer and the second sacrificial layer;
performing an etch-back process on the first sacrificial layer and the first dielectric structure by using the first substrate as a mask to form a first opening exposing the first landing pad, and performing the etch-back process on the second sacrificial layer, the first dielectric structure, and the second dielectric structure by using the first substrate as a mask to form a second opening exposing the second landing pad; and
forming a first through-substrate via (TSV) structure in the first opening, and forming a second TSV structure in the second opening.

2. The manufacturing method of the semiconductor structure according to claim 1, wherein
the first dielectric structure comprises:
a first dielectric layer located on the first substrate, the first sacrificial layer, and the second sacrificial layer, wherein the first landing pad is located in the first dielectric layer; and
a first passivation layer located on the first dielectric layer, and
the second dielectric structure comprises:
a second dielectric layer located on the second substrate, wherein the second landing pad is located in the second dielectric layer; and
a second passivation layer located on the second dielectric layer.

3. The manufacturing method of the semiconductor structure according to claim 2, wherein a method of bonding the first dielectric structure to the second dielectric structure comprises bonding the first passivation layer to the second passivation layer.

4. The manufacturing method of the semiconductor structure according to claim 1, wherein a method of bonding the first dielectric structure to the second dielectric structure comprises a fusion bonding method.

5. The manufacturing method of the semiconductor structure according to claim 1, wherein after the portion of the first substrate is removed, the first sacrificial layer and the second sacrificial layer respectively pass through the first substrate.

6. The manufacturing method of the semiconductor structure according to claim 1, wherein a method of removing the portion of the first substrate comprises a mechanical grinding method, a wet etching method, a chemical mechanical polishing method, or a combination thereof.

7. The manufacturing method of the semiconductor structure according to claim 1, wherein the etch-back process comprises a dry etching process.

8. The manufacturing method of the semiconductor structure according to claim 1, wherein after the first opening and the second opening are formed, a portion of the first sacrificial layer remains on two sides of the first opening, and a portion of the second sacrificial layer remains on two sides of the second opening.

9. The manufacturing method of the semiconductor structure according to claim 1, wherein a cross-sectional shape of the first sacrificial layer and a cross-sectional shape of the second sacrificial layer comprise inverted trapezoids, rectangles, or trapezoids.

10. The manufacturing method of the semiconductor structure according to claim 1, further comprising:
before forming the first TSV structure and the second TSV structure, forming a liner dielectric layer on a sidewall of the first opening and a sidewall of the second opening.
